(19) United States
(12) Patent Application Publication
(10) Pub. No.: US 2021/0011650 A1
(43) Pub. Date: Jan. 14, 2021

(54) CONTROLLER, MEMORY SYSTEM, AND OPERATING METHOD THEREOF

(71) Applicant: SK hynix Inc., Gyeonggi-do (KR)

(72) Inventor: Hyun Woo LEE, Gyeonggi-do (KR)

(21) Appl. No.: 16/667,396

(22) Filed: Oct. 29, 2019

(30) Foreign Application Priority Data
Jul. 8, 2019 (KR) 10-2019-0082103

(51) Int. Cl. G06F 3/06

(52) U.S. Cl. CPC G06F 3/0652; G06F 3/0688; G06F 3/0653; G06F 3/0608; G06F 3/064

(57) ABSTRACT

A controller, a memory system and an operating method thereof are disclosed. The operating method of a controller includes controlling a nonvolatile memory device to perform a first erase operation on invalidated memory blocks; allocating a target memory block for a write operation among the memory blocks on which the first erase operation is performed; controlling the nonvolatile memory device to perform an erase state verifying operation on the target memory block; and controlling the nonvolatile memory device to perform the write operation on the target memory block when the erase state verifying operation indicates that an erase state of the target memory block satisfies a set condition.

### CROSS-REFERENCE TO RELATED APPLICATION

The present application claims priority under 35 U.S.C. § 119(a) to Korean application number 10-2019-0082103, filed on Jul. 8, 2019, in the Korean Intellectual Property Office, which is incorporated herein by reference in its entirety.

### BACKGROUND

### 1. Technical Field

Various embodiments may generally relate to a semiconductor device, and more particularly, to a controller, a memory system, and an operating method thereof.

### 2. Related Art

In recent years, the paradigm for computer environments has transitioned to ubiquitous computing in which computer systems may be used anytime and anywhere. As a result, use of portable electronic apparatuses such as mobile phones, digital cameras, and laptop computers has been increasing rapidly. Generally, portable electronic apparatuses use memory systems that employ memory devices. Memory systems may be used to store data used in the portable electronic apparatuses.

Memory systems using memory devices have no mechanical driving units and exhibit good stability and endurance, fast information access rate, and low power consumption. Such memory systems may include a universal serial bus (USB) memory device, a memory card having various interfaces, a universal flash storage (UFS) device, a solid state drive (SSD), and the like.

### SUMMARY

Embodiments are provided to a technology capable of improving performance of a memory system.

In an embodiment of the present disclosure, an operating method of a controller may include: controlling a nonvolatile memory device to perform a first erase operation on invalidated memory blocks; allocating a target memory block for a write operation among the memory blocks on which the first erase operation is performed; controlling the nonvolatile memory device to perform an erase state verifying operation on the target memory block; and controlling the nonvolatile memory device to perform the write operation on the target memory block when the erase state verifying operation indicates that an erase state of the target memory block satisfies a set condition.

In an embodiment of the present disclosure, a memory system may include: a nonvolatile memory device including a plurality of memory block and a controller configured to control the nonvolatile memory device. The controller may control the nonvolatile memory device to perform a first erase operation on invalidated memory blocks among the plurality of memory blocks; allocate a target memory block for a write operation among the memory blocks on which the first erase operation is performed; control the nonvolatile memory device to perform an erase state verifying operation on the target memory block; and control the nonvolatile memory device to perform the write operation on the target memory block when the erase state verifying operation indicates that an erase state of the target memory block satisfies a set condition.

In an embodiment of the present disclosure, an operating method of a memory system which includes a nonvolatile memory device and a controller configured to control the nonvolatile memory device, the method may include: allocating, by the controller, a target memory block for a write operation among memory blocks registered in a free block list; verifying an erase state of the target memory block; and performing the write operation on the target memory block when the erase state verifying indicates that the erase state of the target memory block satisfies a set condition.

In and embodiment of the present disclosure, an operating method of a controller for controlling a memory device including an invalid memory block, the operating method comprises controlling the memory device to perform a first erase operation on the invalid memory block, which becomes an erased memory block; and controlling, in response to a write command, the memory device to perform a write operation on the erased memory block. The controller controls, in response to the write command, the memory device to perform a second erase operation on the erased memory block before performing the write operation when the erased memory block does not satisfy an erased status condition after the first erase operation.

According to an embodiment of the present disclosure, the performance of a memory system can be improved.

These and other features, aspects, and embodiments are described below.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a diagram illustrating a configuration of a memory system according to an embodiment of the present disclosure;

FIG. 2 is a block diagram illustrating a flash translation layer according to an embodiment of the present disclosure;

FIG. 3 is a flow chart illustrating an operating method of a memory system according to an embodiment of the present disclosure;

FIGS. 4(A), 4(B) and 4(C) are diagrams illustrating an operation of a memory system according to an embodiment of the present disclosure;

FIG. 5 is a diagram illustrating a data processing system including a solid state drive (SSD) according to an embodiment of the present disclosure;

FIG. 6 is a diagram illustrating a configuration of a controller in FIG. 5;

FIG. 7 is a diagram illustrating a data processing system including a memory system according to an embodiment of the present disclosure;

FIG. 8 is a diagram illustrating a data processing system including a memory system according to an embodiment of the present disclosure; and

FIG. 9 is a diagram illustrating a network system including a memory system according to an embodiment of the present disclosure.

### DETAILED DESCRIPTION

Various embodiments of the present invention are described in greater detail with reference to the accompanying drawings. The drawings are schematic illustrations of features, structures and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein in the context of various embodiments of the present invention. However, the present invention is not limited to the disclosed embodiments. Those skilled in the art will understand that changes may be made in these embodiments without departing from the principles and spirit of the present invention. Throughout the specification, reference to “an embodiment” or the like is not necessarily to only one embodiment, and different references to any such phrase are not necessarily to the same embodiment(s).

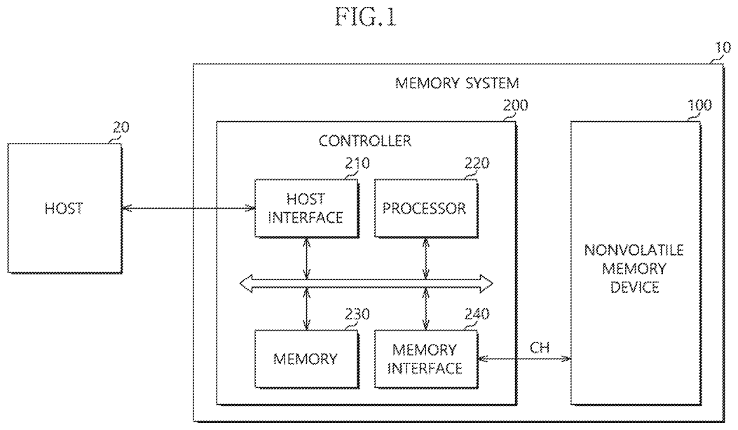

FIG. 1 is a diagram illustrating a configuration of a memory system 10 according to an embodiment.

Referring to FIG. 1, the memory system 10 according to an embodiment may store data to be accessed by a host 20 such as a mobile phone, an MP3 player, a laptop computer, a desktop computer, a game player, a television (TV), an in-vehicle infotainment system, and the like.

The memory system 10 may be configured as any of various types of storage devices according to an interface protocol coupled to the host 20. For example, the memory system 10 may be configured as a solid state drive (SSD), a multimedia card in the form of MMC, eMMC, RS-MMC, and micro-MMC, a secure digital card in the form of SD, mini-SD, and micro-SD, a universal serial bus (USB) storage device, a universal flash storage (UFS) device, a personal computer memory card international association (PCMCIA) card type storage device, a peripheral component interconnection (PCI) card type storage device, a PCI-express (PCI-E) card type storage device, a compact flash (CF) card, a smart media card, a memory stick, or the like.

The memory system 10 may be manufactured as any of various types of packages. For example, the memory system 10 may be manufactured as a package on package (POP), a system in package (SIP), a system on chip (SOC), a multi-chip package (MCP), a chip on board (COB), a wafer-level fabricated package (WFP), or a wafer-level stack package (WSP).

The memory system 10 may include a nonvolatile memory device 100 and a controller 200.

The nonvolatile memory device 100 may be operated as a storage medium of the memory system 10. The nonvolatile memory device 100 may include any of various types of nonvolatile memory devices according to the type of memory cell used, such as a NAND flash memory device, a NOR flash memory device, a ferroelectric random access memory (FRAM) using a ferroelectric capacitor, a magnetic random access memory (MRAM) using a tunneling magneto-resistive (TMR) layer, a phase-change random access memory (PRAM) using a chalcogenide alloy, or a resistive random access memory (ReRAM) using a transition metal compound.

Although it has been illustrated in FIG. 1 that the memory system 10 includes one nonvolatile memory device 100, such presentation is for clarity; the memory system 10 may include a plurality of nonvolatile memory devices 100 and the present disclosure may be equally applied to the memory system 10 including a plurality of nonvolatile memory devices 100.

The nonvolatile memory device 100 may include a memory cell array (not shown) including a plurality of memory cells arranged in regions in which a plurality of word lines (not shown) and a plurality of bit lines (not shown) cross each other. The memory cell array may include a plurality of memory blocks and each of the plurality of memory blocks may include a plurality of pages.

For example, each of the memory cells in the memory cell array may be a single level cell (SLC) in which one bit data is to be stored or a multi level cell (MLC) in which two or more bits of data is to be stored. Sometimes, the MLC may be used to denote a memory cell in which two bits of data is to be stored whereas, a memory cell in which three bits of data is to be stored may be referred to as a triple level cell (TLC), and a memory cell in which four bits of data is to be stored may be referred to as a quadruple level cell (QLC). However, here the MLC refers more generally to a memory cell for storing two or more bits of data.

The memory cell array may include at least one or more SLCs and MLCs. The memory cell array may include memory cells arranged in a two-dimensional (2D) horizontal structure or memory cells arranged in a 3D vertical structure.

The controller 200 may include a host interface 210, a processor 220, a memory 230, and a memory interface 240. The controller 200 may control overall operation of the memory system 10 through driving of firmware or software loaded into the memory 230. The controller 200 may decode and drive a code-type instruction or algorithm such as firmware or software. The controller 200 may be implemented with hardware or a combination of hardware and software. Although not shown in FIG. 1, the controller 200 may further include an error correction code (ECC) engine which generates a parity by performing ECC encoding on write data provided from the host 20 and performs ECC decoding on read data read out from the nonvolatile memory device 100 using the parity.

The host interface 210 may perform interfacing between the host 20 and the memory system 10 according to a protocol of the host 20. For example, the host interface 210 may communicate with the host 20 through any protocol among a USB protocol, a UFS protocol, an MMC protocol, a parallel advanced technology attachment (DATA) protocol, a serial advanced technology attachment (SATA) protocol, a small computer system interface (SCSI) protocol, a serial attached SCSI (SAS) protocol, a PCI protocol, and a PCI-E protocol.

The processor 220 may be configured as a micro control unit (MCU) and/or a central processing unit (CPU). The processor 220 may process requests transmitted from the host 20. To process the requests transmitted from the host 20, the processor 220 may drive a code-type instruction or algorithm (for example, firmware) loaded into the memory 230 and control internal function blocks such as the host interface 210, the memory 230, and the memory interface 240 and the nonvolatile memory device 100.

The processor 220 may generate control signals for controlling operations of the nonvolatile memory device 100 based on the requests transmitted from the host 20 and provide the generated control signals to the nonvolatile memory device 100 through the memory interface 240.

The memory 230 may be configured as a random access memory such as a dynamic random access memory (DRAM) or a static random access memory (SRAM) and a read only memory (ROM). The memory 230 may store the firmware driven through the processor 220. The memory 230 may also store system data and data (for example, meta data) required for driving of the firmware. For example, the memory 230 may be operated as a working memory of the processor 220.

The memory 230 may be configured to include a data buffer configured to temporarily store write data to be transmitted to the nonvolatile memory device 100 from the host 20 or read data to be transmitted to the host 20 from the nonvolatile memory device 100. For example, the memory 230 may be operated as a buffer memory of the processor 220.

As is known in the art, the memory 230 may further include different regions for different purposes, such as a region used as a write data buffer in which write data is to be temporarily stored, a region used as a read data buffer in which read data is to be temporarily stored, and a region used as a map cache buffer in which map data is to be cached.

When the memory device 100 is configured as a flash memory device, the processor 220 may control intrinsic operation of the nonvolatile memory device 100 and drive software called a flash translation layer (FTL) to provide device compatibility to the host 20. The host 20 may recognize and use the memory system 10 as a general storage device such as a hard disc through the driving of the flash translation layer (FTL).

The memory interface 240 may control the nonvolatile memory device 100 according to control of the processor 220. The memory interface 240 may refer to a memory controller. The memory interface 240 may provide control signals to the nonvolatile memory device 100. The control signals may include a command, an address, and an operation control signal, and the like for controlling the nonvolatile memory device 100. The memory interface 240 may provide data stored in the data buffer to the nonvolatile memory device 100 or store data transmitted from the nonvolatile memory device 100 in the data buffer.

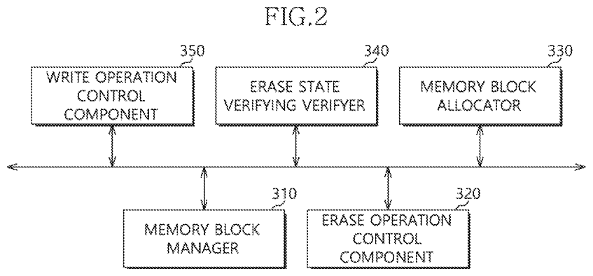

FIG. 2 is a block diagram illustrating a flash translation layer (FTL) according to an embodiment.

Referring to FIG. 2, the flash translation layer may include a memory block manager 310, an erase operation control component 320, a memory block allocator 330, an erase state verifier 340, and a write operation control component 350.

The memory block manager 310 may manage the states of the plurality of memory blocks in the nonvolatile memory device 100. For example, the memory block manager 310 may manage meta data including information on a write operation, a read operation, an erase operation, invalidation, and the like of the plurality of memory blocks or flag information. In this example, when any of the write operation, the read operation, the erase operation, or the like is performed on the plurality of memory blocks or when data stored in the plurality of memory blocks are invalidated, the memory block manager 310 may change the meta data or the flag information according to the operation result or the status of the data, i.e., whether or not such data is invalid.

Further, the memory block manager 310 may register, in a free block list, memory blocks in the nonvolatile memory device 100 and manage the registered memory blocks.

In an embodiment, when at least one of the plurality of memory blocks is invalidated, the memory block manager 310 may register an index of the invalidated memory block(s) in the free block list. When the erase operation is performed on a memory block among the memory blocks registered in the free block list, the memory block manager 310 may map, to the index of the memory block, information indicating that the erase operation was performed on the memory block.

In an embodiment, the memory block manager 310 may register, in the free block list, the index of each memory block on which the erase operation is performed among the invalidated memory blocks.

The erase operation control component 320 may control the nonvolatile memory device 100 to perform the erase operation on the invalidated memory blocks in the nonvolatile memory device 100. Here, the erase operation may include lowering the threshold voltage of each of the plurality of memory cells constituting the memory block to a set erase voltage or less. The nonvolatile memory device 100 may perform the erase operation on the invalidated memory blocks according to control of the erase operation control component 320.

In an embodiment, the erase operation may include repeatedly performing a fixed number of times the set of operations of applying a set voltage to the memory cell and then applying a voltage for verifying the erase state of the memory cell. For example, the erase operation may be a plurality of cycles and each cycle may include an operation of applying an erase voltage and then applying a verify read voltage.

In the description below, an erase operation performed before an invalidated memory block is allocated as a memory block on which a write operation is to be performed may be referred to as a first erase operation, and an erase operation performed after an invalidated memory block is allocated as performed target memory block of the write operation may be referred to as a second erase operation.

In an embodiment, the erase operation control component 320 may perform the first erase operation on the invalidated memory block. For example, when a memory block is invalidated, the erase operation control component 320 may perform the first erase operation on the invalidated memory block before the index of the invalidated memory block is registered in the free block list. The memory block manager 310 may register an index of a memory block on which the erase operation is performed in the free block list.

In an embodiment, the erase operation control component 320 may perform the first erase operation on the memory block registered in the free block list. For example, the erase operation control component 320 may perform the first erase operation on the memory block registered in the free block list after the index of the invalidated memory block is registered in the free block list. The memory block manager 310 may register, in the free block list, the information on whether the erase operation is performed on the registered memory block by mapping the information to the index of the registered memory block in the free block list. The erase operation may be performed on the registered memory block in an idle time of the memory system 10.

When a target memory block of the write operation, among the memory blocks registered in the free block list, is allocated, the erase operation control component 320 may verify the erase state of the allocated memory block and, when the verifying result is abnormal, the erase operation control component 320 may perform the second erase operation on the allocated memory block.

The memory block allocator 330 may allocate a memory block in which data is to be written in response to a write request of the host 20.

In an embodiment, when an index of an invalidated memory block is registered in the free block list, the memory block allocator 330 may select at least one memory block among the memory blocks registered in the free block list as the memory block in which data is to be written.

In an embodiment, when an index of an invalidated but not yet erased memory block is registered in the free block list, the memory block allocator 330 may select, as a target memory block of the write operation, an erased memory block among those registered, based on erase/non-erase information mapped to the indexes of the registered memory blocks.

When the target memory block of the write operation is allocated, the erase state verifier 340 may verify the erase state of the allocated memory block. This verification is performed because sometimes the erase state of the allocated memory block is not properly maintained according to data retention characteristics of the nonvolatile memory device 100 during a stand-by state until the memory block is used.

In an embodiment, the erase state verifier 340 may control the nonvolatile memory device 100 to verify whether threshold voltages of memory cells constituting the allocated memory block are less than or equal to an erase voltage by applying an erase verify voltage to the memory cells and then performing a read operation on the memory cells. The erase state verifier 340 may determine that the erase state is normal when the threshold voltages of the memory cells constituting the allocated memory block are less than or equal to the erase voltage (i.e., passed verification) and determine that the erase state is abnormal when the threshold voltages are greater than the erase voltage (i.e., failed verification).

The write operation control component 50 may control the nonvolatile memory device 100 to perform the write operation which stores data in the allocated memory block. The nonvolatile memory device 100 may perform the write operation according to control of the write operation control component 350.

In an embodiment, the write operation control component 350 may further erase the allocated memory block and then perform the write operation on the allocated memory block when the verifying result of the erase state of the allocated memory block is pass.

In an embodiment, the write operation control component 350 may further perform the second erase operation on the allocated memory block and then perform the write operation on the allocated memory block when the verifying result of the erase state of the allocated memory block is fail.

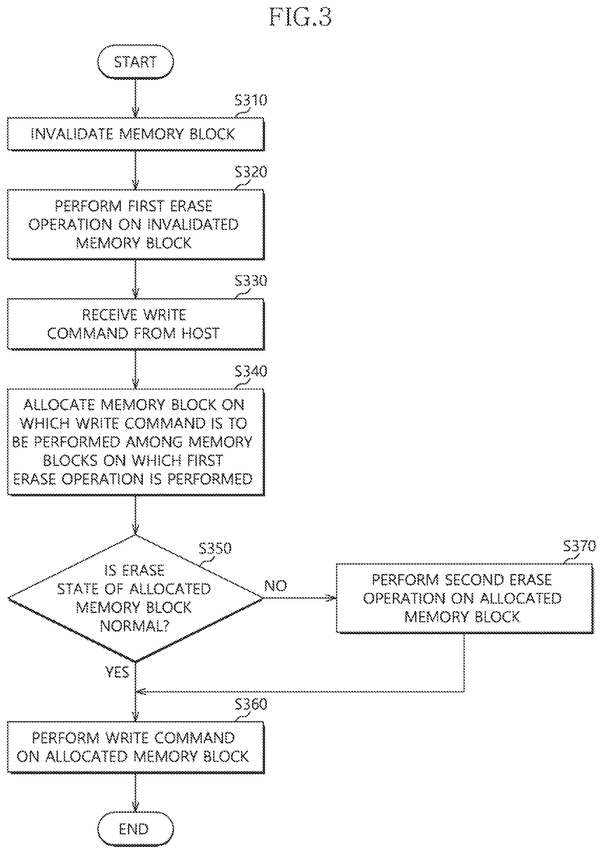

FIG. 3 is a diagram explaining an operating method of a memory system according to an embodiment.

Referring to FIG. 3, in operation S310, the memory system 10 may invalidate memory blocks. For example, the controller 200 may invalidate at least one of memory blocks in the nonvolatile memory device 100.

In an embodiment, when at least one operation, such as garbage collection, migration, and/or read reclaim, is performed on at least one of memory blocks in which data are pre-stored, the controller 200 may invalidate the corresponding memory block(s).

In operation S320, the memory system 10 may perform the first erase operation on the invalidated memory block(s). For example, when at least one memory block is invalidated, the controller 200 may control the nonvolatile memory device 100 to perform the first erase operation which erases the data stored in the invalidated memory block(s).

In an embodiment, the controller 200 may register the invalidated memory block(s) in the free block list. Then, the controller 200 may control the nonvolatile memory device 100 to perform the first erase operation on the invalidated memory block(s) registered in the free block list.

In an embodiment, the controller 200 may control the nonvolatile memory device 100 to perform the first erase operation on the invalidated memory block(s). Then, the controller 200 may register the memory block(s), on which the first erase operation is performed, in the free block list.

In operation S330, the memory system 10 may receive a command, for example, a write command from a host 20.

In operation S340, the memory system 10 may allocate a target memory block of the write operation. For example, when the write command is received from the host 20, the controller 200 may allocate at least one among the memory blocks on which the first erase operation is performed as the target memory block of the write operation with reference to an index of the free block list.

In an embodiment, even though an invalidated memory block, on which the first erase operation is not yet performed, is registered in the free block list, the controller 200 may not allocate such memory block. Instead, the controller 2300 may allocate at least one among the registered memory blocks, on which the first erase operation has been performed, as the target memory block of the write operation.

In an embodiment, when an invalidated memory block, on which the first erase operation has been performed, is registered in the free block list, the controller 200 may allocate at least one among the registered memory blocks as the target memory block of the write operation.

In operation S350, the memory system 10 may verify the erase state of the allocated memory block. For example, the controller 200 may control the nonvolatile memory device 100 to confirm whether the erase state of the allocated memory block is properly maintained. This is to confirm the erase state before the write operation is performed by considering the data retention characteristics according to the time required until the erase operation in operation S340 and then the write operation is performed in operation S360 to be performed later.

In an embodiment, the controller 200 may control the nonvolatile memory device 100 to apply an erase verify voltage to the allocated memory block. The controller 200 may confirm whether the erase state of the allocated memory block has been properly maintained based on the result of having applied the erase verify voltage to the allocated memory block.

In operation S360, the memory system 10 may perform the write operation on the allocated memory block. For example, when it is confirmed that the erase state of the allocated memory block is normal, the controller 200 may control the nonvolatile memory device 100 to perform the write operation on the allocated memory block. In this example, the memory system 10 need not perform the second erase operation on the allocated memory block; instead the write operation is performed on the allocated memory block and thus the time required for the erase operation on the allocated memory block may be reduced in connection with the write operation.

In operation S370, the memory system 10 may perform the second erase operation on the allocated memory block. For example, when it is determined that the erase state of the allocated memory block is abnormal, the controller 200 may control the nonvolatile memory device 100 to perform the second erase operation on the allocated memory block. In this example, the nonvolatile memory device 100 may perform the second erase operation on the allocated memory block according to control of the controller 200. Then, the memory system 10 may perform the write operation on the allocated memory block after the second erase operation for the allocated memory block in operation S370 is completed.

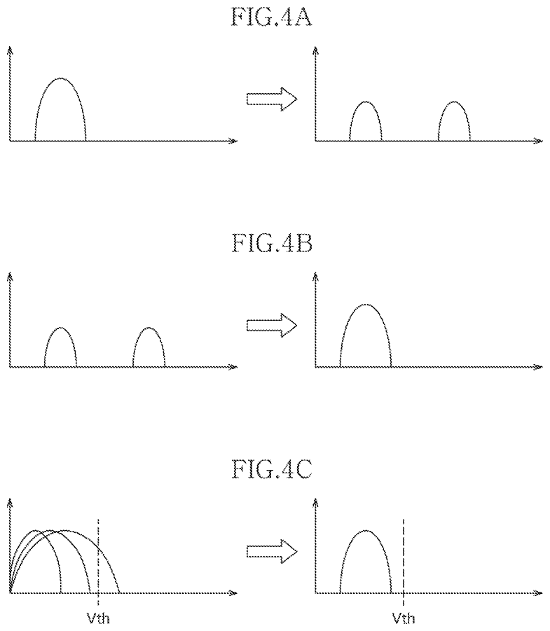

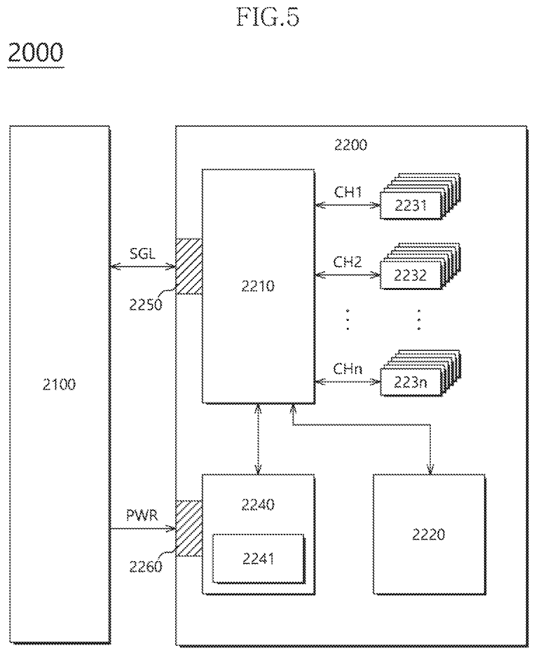

FIGS. 4(A), 4(B) and 4(C) are diagrams explaining an operation of a memory system according to an embodiment.

Referring to FIG. 4(A), the left drawing illustrates the threshold voltage distribution of memory cells on which the write operation has not been performed, and the right drawing illustrates the threshold voltage distribution of the memory cells after performing the write operation on the memory cells. As can be seen, the two threshold voltage distributions are different.

Referring to FIG. 4(B), the left drawing illustrates the threshold voltage distribution of memory cells on which the write operation has been performed, and the right drawing illustrates the threshold voltage distribution of the memory cells after performing the erase operation on the memory cells. It can be seen from FIG. 4(B) that when the first erase operation or the second erase operation according to an embodiment is performed, the threshold voltage distribution of the memory cells may be changed relative to the threshold voltage distribution prior to performing such erase operation.

Referring to FIG. 4(C), the left drawing illustrates that the threshold voltage distribution of memory cells on which the first erase operation is performed changes over time. When the threshold voltage distribution of the memory cells is increased to be greater than a set erase state voltage Vth, the memory system 10 may determine that the erase states of the memory cells are abnormal. When it is determined that the erase states of the memory cells are abnormal, the memory system 10 may perform the second erase operation to have the threshold voltage distribution be less than the set erase state voltage Vth as illustrated in the right drawing of FIG. 4(C).

FIG. 5 is a block diagram illustrating a data processing system including a solid state drive (SSD) according to an embodiment. Referring to FIG. 5, a data processing system 2000 may include a host 2100 and a solid state drive (SSD) 2200.

The SSD 2200 may include a controller 2210, a buffer memory device 2220, nonvolatile memory devices 2231 to 223n, a power supply 2240, a signal connector 2250, and a power connector 2260.

The controller 2210 may control overall operation of the SSD 2200.

The buffer memory device 2220 may temporarily store data which are to be stored in the nonvolatile memory devices 2231 to 223n. Further, the buffer memory device 2220 may temporarily store data which are read out from the nonvolatile memory devices 2231 to 223n. The data temporarily stored in the buffer memory device 2220 may be transmitted to the host 2100 or the nonvolatile memory devices 2231 to 223n according to control of the controller 2210.

The nonvolatile memory devices 2231 to 223n may be used as storage media of the SSD 2200. The nonvolatile memory devices 2231 to 223n may be coupled with the controller 2210 through a plurality of channels CH1 to CHn, respectively. One or more nonvolatile memory devices may be coupled to the same channel. The nonvolatile memory devices coupled to the same channel may be coupled to the same signal bus and data bus.

The power supply 2240 may provide power PWR inputted through the power connector 2260 to the inside of the SSD 2200. The power supply 2240 may include an auxiliary power supply 2241. The auxiliary power supply 2241 may supply power to allow the SSD 2200 to be properly terminated when sudden power-off (SPO) occurs. The auxiliary power supply 2241 may include large capacity capacitors capable of charging the power PWR.

The controller 2210 may exchange a signal SGL with the host 2100 through the signal connector 2250. The signal SGL may include a command, an address, data, and the like. The signal connector 2250 may be configured as any of various types of connectors according to an interface scheme between the host 2100 and the SSD 2200.

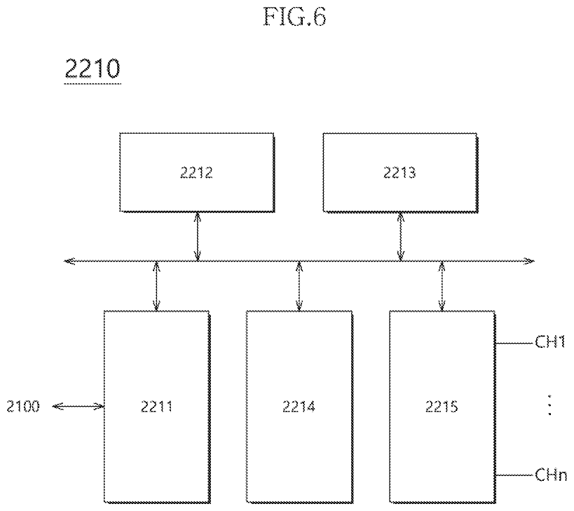

FIG. 6 is a block diagram illustrating the controller illustrated in FIG. 5. Referring to FIG. 6, the controller 2210 may include a host interface 2211, a control component 2212, a random access memory 2213, an error correction code (ECC) component 2214, and a memory interface 2215.

The host interface 2211 may provide interfacing between the host 2100 and the SSD 2200 according to a protocol of the host 2100. For example, the host interface 2211 may communicate with the host 2100 through any one among SD, USB, MMC, embedded MMC (eMMC), PCMCIA, PATA, SATA, SCSI, SAS, PCI, PCI-E, and UFS protocols. In addition, the host interface 2211 may perform a disk emulating function of supporting the host 2100 to recognize the SSD 2200 as a general-purpose memory system, for example, a hard disk drive (HDD).

The control component 2212 may analyze and process the signal SGL inputted from the host 2100. The control component 2212 may control operations of internal function blocks according to firmware or software for driving the SSD 2200. The random access memory 2213 may be used as a working memory for driving such firmware or software.

The ECC component 2214 may generate parity data of data to be transmitted to the nonvolatile memory devices 2231 to 223n. The generated parity data may be stored, along with the data, in the nonvolatile memory devices 2231 to 223n. The ECC component 2214 may detect errors of data read out from the nonvolatile memory devices 2231 to 223n based on the parity data. When the detected errors are within a correctable range, the ECC component 2214 may correct the detected errors.

The memory interface 2215 may provide control signals such as commands and addresses to the nonvolatile memory devices 2231 to 223n according to control of the control component 2212. The memory interface 2215 may exchange data with the nonvolatile memory devices 2231 to 223n according to control of the control component 2212. For example, the memory interface 2215 may provide data stored in the buffer memory device 2220 to the nonvolatile memory devices 2231 to 223n or provide data read out from the nonvolatile memory devices 2231 to 223n to the buffer memory device 2220.

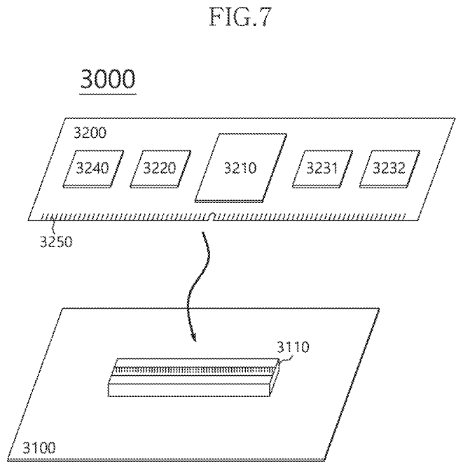

FIG. 7 is a diagram illustrating a data processing system including a memory system according to an embodiment. Referring to FIG. 7, a data processing system 3000 may include a host 3100 and a memory system 3200.

The host 3100 may be configured in the form of a board such as a printed circuit board. Although not shown in FIG. 7, the host 3100 may include internal function blocks for performing functions of the host.

The host 3100 may include a connection terminal 3110 such as a socket, a slot or a connector. The memory system 3200 may be mounted on the connection terminal 3110.

The memory system 3200 may be configured in the form of a board such as a printed circuit board. The memory system 3200 may refer to a memory module or a memory card. The memory system 3200 may include a controller 3210, a buffer memory device 3220, nonvolatile memory devices 3231 and 3232, a power management integrated circuit (PMIC) 3240, and a connection terminal 3250.

The controller 3210 may control overall operation of the memory system 3200. The controller 3210 may be configured in the same manner as the controller 2210 shown in FIG. 5.

The buffer memory device 3220 may temporarily store data to be stored in the nonvolatile memory devices 3231 and 3232. Further, the buffer memory device 3220 may temporarily store data read out from the nonvolatile memory devices 3231 and 3232. The data temporarily stored in the buffer memory device 3220 may be transmitted to the host 3100 or the nonvolatile memory devices 3231 and 3232 according to control of the controller 3210.

The nonvolatile memory devices 3231 and 3232 may be used as storage media of the memory system 3200.

The PMIC 3240 may provide power inputted through the connection terminal 3250, to the inside of the memory system 3200. The PMIC 3240 may manage the power of the memory system 3200 according to control of the controller 3210.

The connection terminal 3250 may be coupled to the connection terminal 3110 of the host 3100. Through the connection terminal 3250, signals such as commands, addresses, data and the like and power may be transferred between the host 3100 and the memory system 3200. The connection terminal 3250 may be configured as any of various types depending on an interface scheme between the host 3100 and the memory system 3200. The connection terminal 3250 may be disposed on any one side of the memory system 3200.

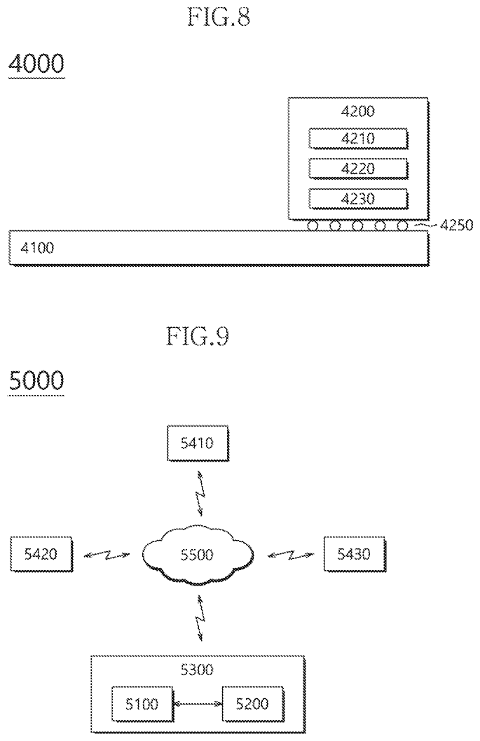

FIG. 8 is a block diagram illustrating a data processing system including a memory system according to an embodiment. Referring to FIG. 8, a data processing system 4000 may include a host 4100 and a memory system 4200.

The host 4100 may be configured in the form of a board such as a printed circuit board. Although not shown in FIG. 8, the host 4100 may include internal function blocks for performing functions of the host.

The memory system 4200 may be configured in the form of a surface-mounting type package. The memory system 4200 may be mounted on the host 4100 through solder balls 4250. The memory system 4200 may include a controller 4210, a buffer memory device 4220, and a nonvolatile memory device 4230.

The controller 4210 may control overall operation of the memory system 4200. The controller 4210 may be configured in the same manner as the controller 2210 shown in FIG. 6.

The buffer memory device 4220 may temporarily store data to be stored in the nonvolatile memory device 4230. Further, the buffer memory device 4220 may temporarily store data read out from the nonvolatile memory device 4230. The data temporarily stored in the buffer memory device 4220 may be transmitted to the host 4100 or the nonvolatile memory device 4230 according to control of the controller 4210.

The nonvolatile memory device 4230 may be used as a storage medium of the memory system 4200.

FIG. 9 is a diagram illustrating a network system 5000 including a memory system according to an embodiment. Referring to FIG. 9, the network system 5000 may include a server system 5300 and a plurality of client systems 5410 to 5430 which are coupled to each other through a network 5500.

The server system 5300 may service data in response to requests from the plurality of client systems 5410 to 5430. For example, the server system 5300 may store data provided from the plurality of client systems 5410 to 5430. In another example, the server system 5300 may provide data to the plurality of client systems 5410 to 5430.

The server system 5300 may include a host 5100 and a memory system 5200. The memory system 5200 may be configured of the memory system 10 illustrated in FIG. 1, the memory system 2200 illustrated in FIG. 6, the memory system 3200 illustrated in FIG. 7, or the memory system 4200 illustrated in FIG. 8.

The above described embodiments of the present invention are intended to illustrate and not to limit the present invention. Various alternatives and equivalents are possible. The invention is not limited by the embodiments described herein. Nor is the invention limited to any specific type of semiconductor device. Thus, the present invention encompasses all additions, subtractions, and modifications that fall within the scope of the appended claims.

What is claimed is:

1. An operating method of a controller which controls a nonvolatile memory device including a plurality of memory blocks, the method comprising:
controlling a nonvolatile memory device to perform a first erase operation on invalidated memory blocks among the plurality of memory blocks;
allocating a target memory block for a write operation among the memory blocks on which the first erase operation is performed;
controlling the nonvolatile memory device to perform an erase state verifying operation on the target memory block; and
controlling the nonvolatile memory device to perform the write operation on the target memory block when the erase state verifying operation indicates that an erase state of the target memory block satisfies a set condition.

2. The method of claim 1,
further comprising registering the memory blocks on which the first erase operation is performed in a free block list,
wherein the allocating of the target memory block includes allocating the target memory block among the registered memory blocks.

3. The method of claim 1,
wherein the controlling of the nonvolatile memory device to perform the first erase operation includes registering the invalidated memory blocks in a free block list and controlling the nonvolatile memory device to perform the first erase operation on the registered memory blocks, and
wherein the allocating of the target memory block includes allocating the target memory block among the registered memory blocks on which the first erase operation was performed.

4. The method of claim 3, wherein the free block list includes indexes of the registered memory blocks and information on whether the first erase operation was performed on each of the registered memory blocks.

5. The method of claim 4, wherein the controller changes the information on whether the first erase operation is performed on the registered memory blocks when the first erase operation is performed on the registered memory blocks.

6. The method of claim 1, wherein the controlling of the nonvolatile memory device to perform the write operation includes controlling the nonvolatile memory device to perform the write operation on the target memory block after the nonvolatile memory device performs a second erase operation on the target memory block when the erase state verifying operation indicates that the erase state of the target memory block does not satisfy the set condition.

7. The method of claim 1, wherein the invalidated memory blocks are invalidated as a result of at least one of a garbage collection operation, a read reclaim operation, and a migration operation.

8. A memory system comprising:
a nonvolatile memory device including a plurality of memory blocks; and
a controller configured to control the nonvolatile memory device,
wherein the controller is configured to:
control the nonvolatile memory device to perform a first erase operation on invalidated memory blocks among the plurality of memory blocks;
allocate a target memory block for a write operation among the memory blocks on which the first erase operation is performed;
control the nonvolatile memory device to perform an erase state verifying operation on the target memory block; and
control the nonvolatile memory device to perform the write operation on the target memory block when the erase state verifying operation indicates that an erase state of the target memory block satisfies a set condition.

9. The memory system of claim 8,
wherein the controller registers the memory blocks on which the first erase operation is performed in a free block list, and
wherein the controller allocates the target memory block among the registered memory blocks.

10. The memory system of claim 8,
wherein the controller registers the invalidated memory blocks in a free block list and controls the nonvolatile memory device to perform the first erase operation on the registered memory blocks, and
wherein the controller allocates the target memory block among the registered memory blocks on which the first erase operation is performed.

11. The memory system of claim 10, wherein the controller registers, in the free block list, indexes of the registered memory blocks and information on whether the first erase operation is performed on each of the registered memory blocks.

12. The memory system of claim 11, wherein the controller changes the information on whether the first erase operation is performed on the registered memory blocks when the first erase operation is performed on the registered memory blocks.

13. The memory system of claim 8, wherein the controller controls the nonvolatile memory device to perform the write operation on the target memory block after the nonvolatile memory device performs a second erase operation on the allocated memory block when the erase state verifying operation for the allocated memory block indicates that the erase state of the target memory block does not satisfy the set condition.

14. The memory system of claim 8, wherein the invalidated memory blocks are invalidated as a result of at least one of a garbage collection operation, a read reclaim operation, and a migration operation.

15. An operating method of a memory system which includes a nonvolatile memory device including a plurality of memory blocks and a controller configured to control the nonvolatile memory device, the method comprising:
allocating, by the controller, a target memory block for a write operation among memory blocks registered in a free block list;
verifying an erase state of the target memory block; and
performing the write operation on the target memory block when the erase state verifying indicates that the erase state of the target memory block satisfies a set condition.

16. The method of claim 15,
wherein the free block list includes indexes of invalidated memory blocks as the registered memory blocks and information on whether an erase operation is performed on the registered memory blocks, and
wherein the allocating of the target memory block includes allocating the target memory block among the registered memory blocks on which the erase operation was performed.

17. The method of claim 16, further comprising controlling the nonvolatile memory device to perform a write operation on the target memory block in response to a write command after the erase operation is performed on the target memory block when the erase state verifying indicates that the erase state of the target memory block does not satisfy the set condition.

18. An operating method of a controller for controlling a memory device including an invalid memory block, the operating method comprising:
controlling the memory device to perform a first erase operation on the invalid memory block, which becomes an erased memory block; and
controlling, in response to a write command, the memory device to perform a write operation on the erased memory block,
wherein the controller controls, in response to the write command, the memory device to perform a second erase operation on the erased memory block before performing the write operation when the erased memory block does not satisfy an erased status condition after the first erase operation.
